(19) United States
(12) Patent Application Publication
(10) Pub. No.: US 2009/0224327 A1
(43) Pub. Date: Sep. 10, 2009

(54) PLANE MOS AND THE METHOD FOR MAKING THE SAME

(76) Inventors: En-Chiuan Liou, Tainan County (TW); Shih-Fang Hong, Tainan County (TW); Chih-Wei Yang, Kao-Hsiung Hsien (TW); Yu-Hsin Lin, Hsinchu City (TW); Rai-Min Huang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/041,666

(22) Filed: Mar. 4, 2008

(51) Int. Cl. H01L 29/78; H01L 21/336

(52) U.S. Cl. 257/368; 438/289; 257/E29.255; 257/E21.409

(57) ABSTRACT

A plane MOS includes a substrate, an insulator layer whose surface is substantially parallel with the surface of the substrate disposed on the substrate, a gate, a source and a drain directly disposed on the insulator layer and a gate channel disposed between the source and the drain and contacting the gate.

### BACKGROUND OF THE INVENTION

1. Field of the Invention

The present invention relates to a metal-oxide semiconductor (MOS). More particularly, the present invention relates to a plane MOS.

2. Description of the Prior Art

Transistors made of MOS are widely used. The conventional transistor structure consists of a gate, a source and a drain. The source and the drain are respectively disposed in a substrate. The gate is formed on the substrate and between the source and the drain to be in charge of controlling the on/off state of the current in the gate channel sandwiched between the source and the drain, and under the gate.

In order to arrange more transistors in the substrate of same area to lower the cost, the size of the gate, the source and the drain shrinks as the critical dimension shrinks. Due to the intrinsic physical limit of the material, the shrinkage of the gate, the source and the drain leads to the decrease of carriers determining the quantity of the current in the transistor to a degree which makes the transistor almost impossible to operate. In order to compensate the loss of the carriers in the transistor, the length of the gate, the source and the drain would have no choice but to be elongated, i.e. the width of the gate channel is increased. Because the length of the gate, the source and the drain extends along the direction substantially parallel with the surface of the substrate, the elongation of the gate, the source and the drain, i.e. the increase of the width of the gate channel, will inevitably decrease the density of the elements on the substrate and adversely sacrifice the integration of the integrated circuits, which is not an ideal solution at all.

Therefore, a novel semiconductor device is needed on one hand to effectively increase the density of the transistors on the substrate, and on the other hand to maintain sufficient carriers which determine the quantity of the current in the transistor.

### SUMMARY OF THE INVENTION

The present invention therefore provides a novel semiconductor device. In this novel semiconductor device, the length of the gate, the source and the drain, i.e. the width of the gate channel, extends along the direction perpendicular to the surface of the substrate. Accordingly, even though the length of the gate, the source and the drain is elongated to maintain sufficient carriers in the transistor, and the density of the elements on the substrate is not compromised. This is an excellent solution.

The present invention first provides a plane MOS, including a substrate, an insulator layer whose surface is substantially parallel with the surface of the substrate disposed on the substrate, a gate, a source and a drain directly disposed on the insulator layer and a gate channel disposed between the source and the drain and contacting the gate, so that the length of the gate, the source and the drain, i.e. the width of the gate channel, extends along the direction perpendicular to the surface of the substrate.

The present invention again provides a plane MOS, including a substrate, an insulator layer whose surface is substantially parallel with the surface of said substrate disposed on the substrate, a first source and a first drain directly disposed on the insulator layer, a first gate channel located between the first source and the first drain, a second source and a second drain directly disposed on the insulator layer, a second gate channel located between the second source and the second drain, and a gate sandwiched between the first gate channel and the second gate channel, so that not only do the first source and the first drain, the second source and the second drain share the common gate, but also the length of the gate, the first source, the first drain, the second source and the second drain, i.e. the width of the gate channel, extends along the direction perpendicular to the surface of the substrate.

The present invention still provides a plane semiconductor inverter, including a substrate, an insulator layer whose surface is substantially parallel with the surface of the substrate disposed on said substrate, a first source and a first drain directly disposed on the insulator layer, a first gate channel located between the first source and the first drain, a second source and a second drain directly disposed on the insulator layer, a second gate channel located between the second source and the second drain, and a gate sandwiched between the first gate channel and the second gate channel, wherein the gate, the first source, the first drain and the first gate channel together form a PMOS and the gate, the second source, the second drain and the second gate channel together form an NMOS, so that not only do the PMOS and the NMOS share the common gate, but also the length of the gate, the first source, the first drain, the second source and the second drain, i.e. the width of the gate channel, extends along the direction perpendicular to the surface of the substrate.

The present invention provides a method for forming a plane MOS. First a substrate having an insulator layer thereon whose surface is substantially parallel with the surface of the substrate, an active area directly on the surface of the insulator layer and a shallow trench isolation surrounding the active area are provided. Then the threshold voltage of the active area is adjusted. Later, a first hard mask covering the active area and the shallow trench isolation and a patterned second hard mask covering the first hard mask are formed, wherein the second patterned hard mask exposes a gate region, source region and a drain region of the first hard mask. Afterwards, the first hard mask is etched back to expose the active area of the source region and the active area of the drain region through the source region and the drain region. Then, a source and a drain are respectively formed in the exposed active area of the source region and the active area of the drain region. Later, a passivation layer is formed to cover the first hard mask, the second hard mask, the source and the drain. Afterwards, the gate region is etched to expose the insulator layer and to form a gate trench in the active area. Then the passivation layer is removed. Later, the gate trench is substantially filled with a conductive material to form a gate. Afterwards, a gate contact plug, a source contact plug and a drain contact plug are respectively formed on the gate, the source and the drain to form the plane MOS, so that the length of the gate, the source and the drain, i.e. the width of the gate channel, extends along the direction perpendicular to the surface of the substrate.

The present invention further provides a method for forming a plane dual-channel structure. The plane dual-channel structure includes a PMOS and an NMOS sharing a common gate. The method includes first providing a substrate having an insulator layer thereon, whose surface is substantially parallel with the surface of the substrate, and further a PMOS active area, an NMOS active area and a gate region directly disposed on the surface of the insulator layer, a shallow trench isolation respectively surrounding the PMOS active area and the NMOS active area. Then the threshold voltage of the PMOS active area and the NMOS active area is adjusted. Afterwards, a first hard mask covering the PMOS and NMOS active area, the gate region and the shallow trench isolation, and a patterned second hard mask covering the first hard mask are formed, wherein the patterned second hard mask defines a PMOS source region, a PMOS drain region, an NMOS source region, an NMOS drain region and a gate region. Afterwards, the first hard mask is etched back to expose the PMOS active area of the PMOS source region, the PMOS active area of the PMOS drain region, the NMOS active area of the NMOS source region and the NMOS active area of the NMOS drain region through the PMOS source region, the PMOS drain region, the NMOS source region and the NMOS drain region. Later, a PMOS source and a PMOS drain are respectively formed in the exposed PMOS active area of the PMOS source region and the PMOS active area of the PMOS drain region. Afterwards, an NMOS source and an NMOS drain are respectively formed in the exposed NMOS active area of the NMOS source region and the NMOS active area of the NMOS drain region. Then, a passivation layer is formed to cover the partially exposed first hard mask, the second hard mask, the PMOS source, the PMOS drain, the NMOS source and the NMOS drain. Afterwards, the gate region is etched to expose the corresponding insulator layer and a gate trench is formed. Later, a gate insulator layer is formed on the sidewall of the gate trench and a gate is formed by filling the gate trench with a conductive material. Then, the conductive material is etched back and the passivation layer is removed. Afterwards, a gate contact plug, a PMOS source contact plug, a PMOS drain contact plug, an NMOS source contact plug and an NMOS drain contact plug are respectively formed on the gate, the PMOS source, the PMOS drain, the NMOS source and the NMOS drain to form the plane dual-channel structure, so that the PMOS and the NMOS share a common gate. Also, the length of the gate, the PMOS source, the PMOS drain, the NMOS source and the NMOS drain, i.e. the width of the gate channel, extends along the direction perpendicular to the surface of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a preferred embodiment of the plane MOS of the present invention.

FIG. 2 illustrates another preferred embodiment of the plane MOS of the present invention.

FIGS. 3-11 illustrate a preferred embodiment of the method for forming the semiconductor structure of the present invention.

FIG. 12 illustrates a preferred embodiment for forming a gate region in the common gate semiconductor structure of the present invention.

### DETAILED DESCRIPTION

The present invention provides a novel semiconductor device. In this novel semiconductor device, the length of the gate, the source and the drain, i.e. the width of the gate channel, extends along the direction perpendicular to the surface of the substrate. Consequently, even though the length of the gate, the source and the drain is elongated to widen the width of the gate channel in order to maintain sufficient carriers in the transistor, the original density of the transistors on the substrate is not compromised. This is an excellent solution to increase the integration of the integrated circuits.

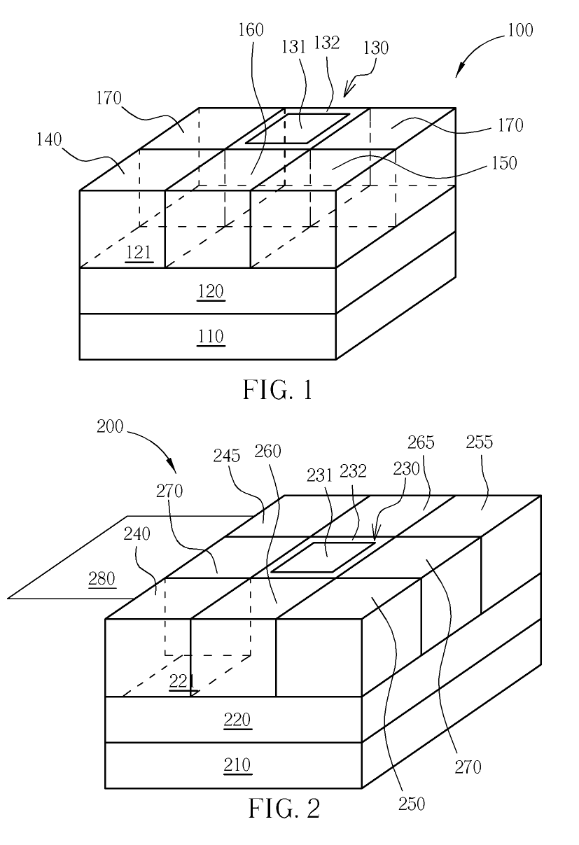

The present invention first provides a plane MOS. FIG. 1 illustrates a preferred embodiment of the plane MOS of the present invention. Please refer to FIG. 1, the plane MOS 100 of the present invention includes a substrate 110, an insulator layer 120, a gate 130, a source 140 and a drain 150 and a gate channel 160. The insulator layer 120 is disposed on the substrate 110 so that the surface 121 of the insulator layer 120 is substantially parallel with the surface of the substrate 110. The substrate 110 may be a semiconductor material, such as Si or SOI. The insulator layer 120 may be an oxide, such as a buried oxide.

The gate 130, the source 140 and the drain 150 are respectively directly disposed on the surface 121 of the insulator layer. The gate channel 160 is located between the source 140 and the drain 150. The gate 130 contacts the gate channel 160, so that the gate 130 is able to control the on and off state of the gate channel 160. The threshold voltage of the gate channel 160 may be adjusted by adjusting the concentration of the dopants in the gate channel 160.

The gate 130 may include a gate conductor 131 and a gate insulator layer 132. The gate conductor 131 may be a single or a composite conductive material, such as silicon or metal. The gate insulator layer 132 surrounds the gate conductor 131 so that the gate 130 is electrically isolated from the source 140, the drain 150 and the gate channel 160. The gate insulator layer 132 may be an oxide formed by thermal process or deposition process such as silicon dioxide, or a high-k (high dielectric constant) dielectric material formed by deposition such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate, or a combination thereof.

The plane MOS 100 of the present invention may further include a shallow trench isolation 170 surrounding and contacting the gate 130, the source 140, the drain 150 and the gate channel 160 to maintain the electrical isolation between different plane MOSs 100.

The plane MOS 100 of the present invention is a fully depleted transistor, which has the advantage of low leakage current. In this semiconductor structure, the length of the gate, the source and the drain, i.e. the width of the gate channel, extends along the direction perpendicular to the surface of the substrate. So, even though the length of the gate, the source and the drain is elongated to maintain sufficient carriers in the transistor, no area is additionally occupied and the density of the transistors on the substrate is not influenced or compromised.

The present invention again provides another plane MOS. FIG. 2 illustrates another preferred embodiment of the plane MOS of the present invention. Please refer to FIG. 2, the plane MOS 200 of the present invention includes a substrate 210, an insulator layer 220, a gate 230, a first source 240, a first drain 250, a first gate channel 260, a second source 245, a second drain 255 and a second gate channel 265. The insulator layer 220 is disposed on the substrate 210, so that the surface 221 of the insulator layer 220 is substantially parallel with the surface of the substrate 210. The substrate 210 may be a semiconductor material, such as Si or SOI. The insulator layer 220 may be an oxide, such as a buried oxide.

The gate 230, the first source 240, the first drain 250, the second source 245 and the second drain 255 are respectively directly disposed on the surface 221 of the insulator layer 220. Besides, a first gate channel 260 is formed between the first source 240 and the first drain 250, and a second gate channel 265 is formed between the second source 245 and the second drain 255. The gate 230 is sandwiched between the first gate channel 260 and the second gate channel 265, and respectively contacts the first gate channel 260 and the second gate channel 265, so that the gate 230 is a common gate to simultaneously control the on and off state of the first gate channel 260 and the second gate channel 265. The term “sandwiched” means located between two reference objects and directly or indirectly contacts those reference objects, and preferably directly contacts those reference objects. The threshold voltage of each gate channel 260/265 may be adjusted by adjusting the concentration of the dopants in the first gate channel 260 and in the second gate channel 265. The electric conductivity of the dopants in the first source 240/first drain 250 may be the same as or different from that in the second source 245/second drain 255.

The gate 230 may include a gate conductor 231 and a gate insulator layer 232. The gate conductor 231 may include a single or a composite conductive material, such as silicon or metal. The gate insulator layer 232 surrounds the gate conductor 231 so that the gate 230 is respectively electrically isolated from the first source 240, the first drain 250, the first gate channel 260 and the second source 245, the second drain 255, the second gate channel 265. The gate insulator layer 232 may be an oxide formed by thermal process or deposition process such as silicon dioxide, or a high-k (high dielectric constant) dielectric material formed by deposition such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate, or a combination thereof.

In addition, the first source 240 and the second source 245 in the plane MOS 200 of the present invention may be electrically connected through an interconnect 280 including conductive plugs and metal layers (not shown), as shown in FIG. 2. When the first source 240 and the second source 245 are electrically connected, it becomes a so-called “common source.”

The plane MOS 200 of the present invention may further include a shallow trench isolation 270 to contact, preferably to surround the gate 230, the first source 240, the first drain 250, the first gate channel 260, the second source 245, the second drain 255 and the second gate channel 265 to maintain the electrical isolation between different plane MOSs 200.

The plane MOS 200 of the present invention is a common gate, dual-channel and fully depleted transistor. The common gate of dual-channel has the advantage of increasing the density of elements and decreasing the isolation between different ion wells, and full depletion has the advantage of low leakage current. In this semiconductor structure, the length of the gate, the source and the drain, i.e. the width of the gate channel, extends along the direction perpendicular to the surface of the substrate. So, even though the length of the gate, the source and the drain is elongated to maintain sufficient carriers in the transistor, no area is additionally occupied and the density of the transistors on the substrate is not influenced or compromised.

Generally speaking, MOS may be divided into P-type metal-oxide semiconductor or N-type metal-oxide semiconductor, PMOS or NMOS for short, according to the different polarity of its “channel.”

As far as design is concerned, the PMOS or the NMOS each has its different threshold voltages, which are determined by the difference of the work function of the materials in the gate and in the channel, usually accomplished by two different metals as the materials in the channel. Accordingly, the plane MOS of the present invention may further employ at least two different metals disposed in the common gate to be the gate conductor material respectively for the PMOS and for the NMOS.

The present invention still provides a plane semiconductor inverter, as shown in FIG. 2.

For example, the gate 230, the first source 240, the first drain 250 and the first gate channel 260 may together form a PMOS. Similarly, the gate 230, the second source 245, the second drain 255 and the second gate channel 265 may together form an NMOS, so the plane semiconductor inverter of the present invention is the combination of the PMOS formed of the gate 230, the first source 240, the first drain 250 and the first gate channel 260, and the NMOS formed of the gate 230, the second source 245, the second drain 255 and the second gate channel 265.

The selection of the materials of the gate conductor 231 of the gate 230 is midgate materials due to the gate 230 being shared by both the PMOS and the NMOS, the gate conductor 231 may include a conductive material whose work function is between its conduction band and its valence band, for example MoN and TaSIN, to meet the requirements. In other words, the conductive material includes a P-type gate material for a PMOS such as ruthenium, palladium, platinum, cobalt, nickel, and the conductive metal oxide thereof and an N-type gate material for an NMOS such as hafnium, zirconium, titanium, tantalum, aluminum, and their alloys.

Because the gate conductor 231 may include composite materials, it may include materials of different work functions. Hence, the plane MOS of the present invention may further employ at least two different metals of different work functions disposed in the common gate to be the gate conductor materials respectively of the PMOS and in the NMOS. The structure of the semiconductor device is simple and easy to be manufactured.

T plane semiconductor inverter 200 of the present invention forms a so-called “common source.”

The plane semiconductor inverter 200 of the present invention may further include a shallow trench isolation 270 to maintain the electrical isolation between different plane MOSs.

The plane semiconductor inverter 200 of the present invention may also have the same benefits as described in the above-mentioned embodiments.

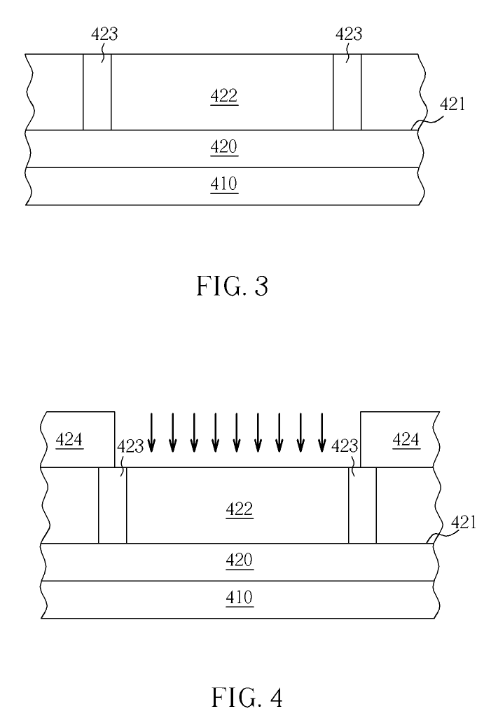

The present invention also provides a method for forming a novel plane MOS structure. FIGS. 3-11 illustrate a preferred embodiment of the method for forming the semiconductor structure of the present invention. Please refer to FIG. 3, the method for forming the plane MOS of the present invention first a substrate 410 is provided. The substrate 410 has an insulator layer 420 thereon. The surface 421 of the insulator layer 420 is substantially parallel with the surface of the substrate 410. There is a semiconductor layer, which includes an active area 422 and a shallow trench isolation 423 surrounding the active area 422, directly disposed on the surface 421. The substrate 410 may be a semiconductor material, such as Si or SOI. The insulator layer 420 may be an oxide, such as a buried oxide. The shallow trench isolation 423 may be formed by a conventional STI process in the semiconductor layer on the insulator layer 420. The details will not be discussed here.

Then, please refer to FIG. 4, the threshold voltage of the active area 422 is adjusted. For example, the active area 422 may be exposed by the definition of a photoresist 424 and implanted with dopants, so that the threshold voltage of the active area 422 is adjusted with the help of dopants.

After the photoresist 424 is removed, please refer to FIG. 5, a first hard mask 425 covering the active area 422 and the shallow trench isolation 423 and a second patterned hard mask 426 covering the first hard mask 425 are formed. The patterned second hard mask 426 is on the top to expose the first hard mask 425 defining a gate region 431, a source region 441 and a drain region 451. The first hard mask 425 and the second hard mask 426 may be of different materials, such as different materials of different etching selectivity.

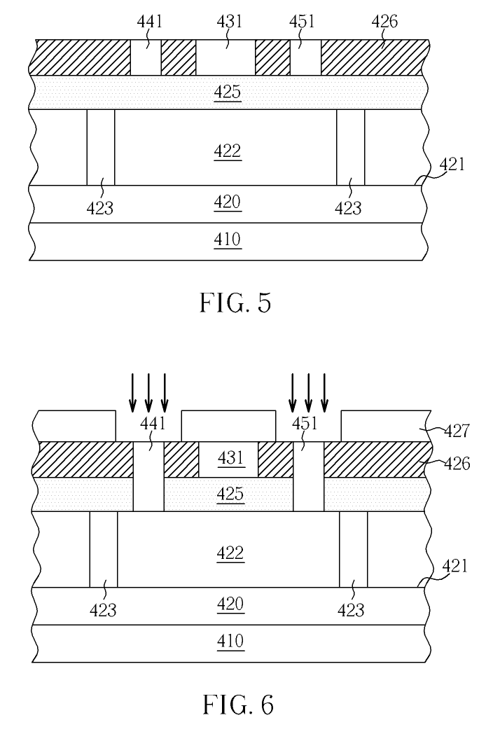

Afterwards, please refer to FIG. 6, the source region 441 and the drain region 451 on the first hard mask 425 is removed through a pattern transferring procedure, such as a dry etching or a wet etching. For example, a patterned photoresist 427 is used to shield the openings of the gate region 431 on the second hard mask 426, and using the patterned photoresist 427 and the second hard mask 426 as hard masks to etch the first hard mask 425 to define the patterns of the source region 441 and the drain region 451 on the first hard mask 425 and to expose the source region 441 and the drain region 451 of the active area 422.

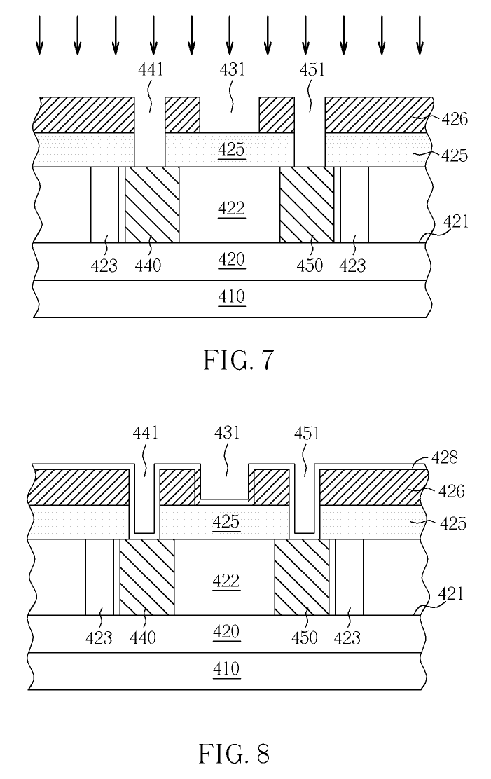

Then, please refer to FIG. 7, a source 440 and a drain 450 are respectively formed in the exposed source region 441 and the drain region 451 of the active area 422. The procedure for forming the source 440 and the drain 450 may be, for example, using a photoresist 427 and the second hard mask 426 as hard masks to perform ion implantation, such as P-type dopants or N-type dopants, on the source region 441 and the drain region 451 of the active area 422. The proper electric property of the source 440 and the drain 450 may be established after annealing. Please note that, the dopant may be laterally diffusing due to the annealing procedure, so the width of the actual source 440 and drain 450 may be larger than that of the implanted source region 441 and drain region 451.

After the photoresist 427 is removed, please refer to FIG. 8, a passivation layer 428 is formed to cover the partially exposed first hard mask 426, the patterned second hard mask 425, the source 440 and the drain 450. The passivation layer 428 may include a nitride, such as silicon nitride.

Please refer to FIG. 9, now a gate trench 432 is about to be formed. The procedure for forming the gate trench 432 may be etching the active area 422 through the openings of the gate region 431 on the second hard mask 426 to expose the insulator layer 420 to form the gate trench 432 in the active area 422. For example, a patterned photoresist 429 may be used to shield openings of the source region 441 and the drain region 451 on the second hard mask 426 and using the photoresist 429 and the second hard mask 426 as hard masks to etch the passivation layer 428, the first hard mask 425 and the active area 422 until the surface 421 of the insulator layer 420 is exposed to define the gate region 431 in the active area 422.

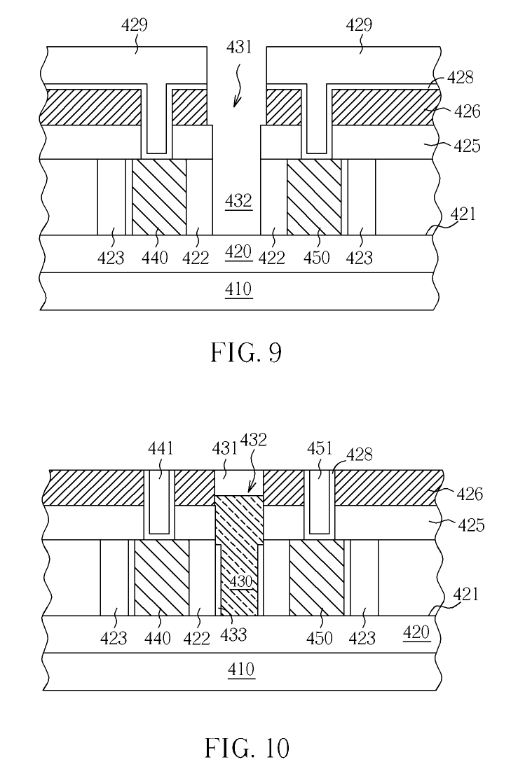

Afterwards, please refer to FIG. 10, after the photoresist 429 is removed, a gate isolation layer 433 is formed on the side wall of the exposed active area 422 in the gate trench 432 by a rapid thermal oxidation (RTO) or a deposition procedure, then the openings of the gate trench 432, the source region 441 and the drain region 451 are filled with conductive materials, such as poly-Si or metal. The gate insulator layer 433 may be an oxide formed by thermal process or deposition process such as silicon dioxide, or a high-k (high dielectric constant) dielectric material formed by deposition such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate, or a combination thereof. Later, part of the conductive materials and the passivation layer 428 are removed by a CMP process until the second hard mask 426 is exposed and the sidewalls of the opening pattern and the underlying passivation layer 428 of the source region 441 and the drain region 451 are remained. Last, steps such as etching back are performed to remove the conductive materials in the openings of the source region 441 and the drain region 451 of the first hard mask 425 and the second hard mask 426 and part of the conductive materials in the gate trench 432.

Then, the passivation layer is removed to expose the source and drain of the PMOS as well as the source and drain of the NMOS.

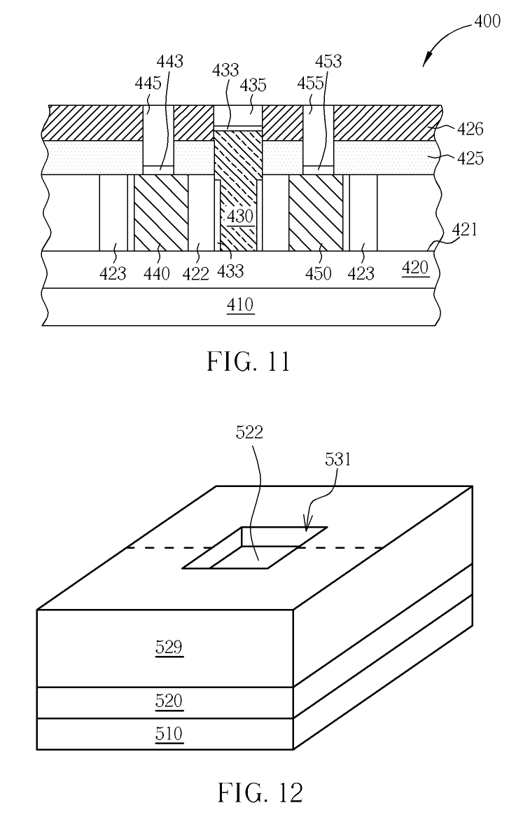

To be continued, please refer to FIG. 11, a gate contact plug 435, salicide 433, a source contact plug 445, salicide 443 and a drain contact plug 455, salicide 453 are respectively formed on the gate 430, the source 440 and the drain 450 to complete the formation of the MOS 400. The procedure for forming the gate contact plug 435, the source contact plug 445 and the drain contact plug 455 may be that, for example, corresponding suicides 433/443/453 are first formed on the corresponding surface of the gate 430, the source 440 and the drain 450 to lower the contact resistance between the metal plugs and the gate region, the source region and the drain region by using metal(s) and by performing a self-aligned silicidation or SALICIDE, then a contact plug procedure is performed to fill a proper barrier layer and a conductive layer, such as W, to form the gate contact plug 435, the source contact plug 445 and the drain contact plug 455.

The above is an example of the method of forming a single plane metal-oxide semiconductor. Similarly, the present invention may be useful in forming a plane metal-oxide semiconductor with common gate structure. If a PMOS and an NMOS are both formed on the same substrate by the method of forming metal-oxide semiconductor of the present invention, the NMOS may be first formed then the PMOS or in similar steps, the PMOS may be first formed then the NMOS.

The following illustrates the method to respectively form a PMOS and an NMOS on the same substrate and generally refers to the steps in FIGS. 3-11. First a substrate is provided with an insulator layer thereon, whose surface is respectively substantially parallel with the surface of the substrate. There are also a PMOS active area directly disposed on the surface of the insulator layer, an NMOS active area directly disposed on the surface of the insulator layer, a shallow trench isolation respectively surrounding the PMOS active area and the NMOS active area. Please refer to FIG. 3 for the details.

Then, the threshold voltage of the PMOS active area/NMOS active area may be respectively adjusted. For example, different dopants may be employed to respectively adjust the threshold voltage of the PMOS active area and the NMOS active area. Please refer to FIG. 4 for the details.

Afterwards, similar to what is illustrated in FIG. 5, a first hard mask covering the PMOS active area, the NMOS active area, the gate region, and the shallow trench isolation, and a patterned second hard mask covering the first hard mask are formed. The patterned second hard mask defines a PMOS source region, a PMOS drain region, an NMOS source region, an NMOS drain region and a gate region. Both first/second hard masks cover the active area and the shallow trench isolation.

Please refer to FIG. 2, if the PMOS and the NMOS with common gate are intended to be formed, the second hard mask may define a gate region 230.

Afterwards, similar to what is illustrated in FIG. 6, the first hard mask is etched back to expose the PMOS active area of the PMOS source region and the PMOS active area of the PMOS drain region through the PMOS source region and the PMOS drain region, and the first hard mask is etched back to expose the NMOS active area of the NMOS source region and the NMOS active area of the NMOS drain region through the NMOS source region and the NMOS drain region.

Later, similar to what is illustrated in FIG. 7, a PMOS source and a PMOS drain are respectively formed in the exposed PMOS active area of the PMOS source region and the PMOS active area of the PMOS drain region, as well as an NMOS source and an NMOS drain are respectively formed in the exposed NMOS active area of the NMOS source region and the NMOS active area of the NMOS drain region.

Then, similar to what is illustrated in FIG. 8, a passivation layer is formed to cover the partially exposed first hard mask, the patterned second hard mask, the PMOS source, the PMOS drain, the NMOS source and the NMOS drain.

For an independent PMOS and NMOS structure, each gate region is respectively etched to expose the corresponding insulator layer and to form the gate trenches in the corresponding active area. However, for a semiconductor structure with common gate, as shown in FIG. 12, under the protection of a mask 529, the active area 522 in the gate region 531 is etched to expose the insulator layer 520 on the substrate 510 and a gate trench is formed. Then, part of the passivation layer may be removed, as mentioned before.

Afterwards, as previously mentioned, the gate insulation layer is formed; the conductive material is filled in the gate trench; the excess conductive material is removed by polishing and the conductive material is etched back. The gate insulator layer may be an oxide formed by thermal process or deposition process such as silicon dioxide, or a high-k (high dielectric constant) dielectric material formed by deposition such as hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate, or a combination thereof. Then, as previously mentioned, the passivation layer is removed to expose the source and drain of the PMOS as well as the source and drain of the NMOS.

Later, the gate, the gate contact plug, the source contact plug, and the drain contact plug are formed to complete the plane dual-channel structure. For an independent PMOS and NMOS structure, the method for forming the gate, the gate contact plug, the source contact plug, and the drain contact plug are as mentioned before. However, for a semiconductor structure with common gate, the selection of the gate conductive materials in the gate is critical if the conductive materials are about to fill the gate trench to form the gate.

The selection of the gate conductive materials depends on if a PMOS or an NMOS is formed by the source, the drain and the gate channel. For example, if the gate, the second source, the second drain and the second gate channel together form an NMOS and the gate, the first source, the first drain and the first gate channel together form a PMOS, the gate is formed of a midgate material, and the gate conductor may include a conductive material whose work function is between its conduction band and its valence band, for example MoN or TaSIN. In other words, the conductive material includes a P-type gate material for a PMOS such as ruthenium, palladium, platinum, cobalt, nickel, and the conductive metal oxide thereof and an N-type gate material for an NMOS such as hafnium, zirconium, titanium, tantalum, aluminum, and their alloys, such as a composite material. In order to form electric isolation from the source, the drain and the gate channel, the gate may further include a gate isolation layer surrounding the conductive material in addition to the conductive material.

Optionally, the PMOS source and the NMOS source in the plane dual-channel structure of the present invention may be electrically connected through an interconnect, as shown in FIG. 2. When the PMOS source and the NMOS source are electrically connected, it becomes a “common source.”

In this novel semiconductor device of the present invention, the length of the gate, the source and the drain, i.e. the width of the gate channel, extends along the direction perpendicular to the surface of the substrate. Hence, even though the length of the gate, the source and the drain is elongated to maintain sufficient carriers in the transistor, the density of the transistors on the substrate is not compromised. Further, if the semiconductor has shared common gates, the density of the transistors may be further enhanced. This indeed is an excellent solution.

Those skilled in the art will readily observe that numerous modifications and alterations of the device and method may be made while retaining the teachings of the invention.

What is claimed is:

1. A plane metal-oxide semiconductor (MOS), comprising:
a substrate;
an insulator layer, whose surface is substantially parallel with the surface of said substrate, disposed on said substrate;
a gate directly disposed on said insulator layer;
a source directly disposed on said insulator layer;
a drain directly disposed on said insulator layer; and
a gate channel located between said source and said drain and contacting said gate.

2. The plane MOS of claim 1, wherein said gate comprises a gate conductor and a gate insulator layer.

3. The plane MOS of claim 2, wherein said gate insulator layer comprises silicon dioxide, high-k dielectric material, or a combination thereof.

4. The plane MOS of claim 1, further comprising a shallow trench isolation to contact said source, said drain and said gate.

5. A plane MOS, comprising:
a substrate;
an insulator layer, whose surface is substantially parallel with the surface of said substrate, disposed on said substrate;
a first source directly disposed on said insulator layer;
a first drain directly disposed on said insulator layer;
a first gate channel located between said first source and said first drain;
a second source directly disposed on said insulator layer;
a second drain directly disposed on said insulator layer;
a second gate channel located between said second source and said second drain; and
a gate sandwiched between said first gate channel and said second gate channel.

6. The plane MOS of claim 5, wherein said first source and said second source are electrically connected by an interconnect structure.

7. The plane MOS of claim 5, further comprising a shallow trench isolation on said insulator layer to render said first source, said first drain, said second source and said second drain mutually electrically insulated.

8. The plane MOS of claim 7, wherein said gate comprises a gate conductor and a gate insulator layer.

9. The plane MOS of claim 8, wherein said gate insulator layer comprises silicon dioxide, high-k dielectric material, or a combination thereof.

10. A plane semiconductor inverter, comprising:
a substrate;
an insulator layer, whose surface is substantially parallel with the surface of said substrate, disposed on said substrate;
a first source directly disposed on said insulator layer;
a first drain directly disposed on said insulator layer;
a first gate channel located between said first source and said first drain;
a second source directly disposed on said insulator layer;
a second drain directly disposed on said insulator layer;
a second gate channel located between said second source and said second drain; and
a gate sandwiched between said first gate channel and said second gate channel, wherein said gate, said first source, said first drain and said first gate channel together form a PMOS and said gate, said second source, said second drain and said second gate channel together form an NMOS.

11. The plane semiconductor inverter of claim 10, wherein said first source and said second source are electrically connected by an interconnect structure.

12. The plane semiconductor inverter of claim 10, wherein said gate comprises a gate conductor and a gate insulator layer.

13. The plane semiconductor inverter of claim 12, wherein said gate insulator layer comprises silicon dioxide, high-k dielectric material, or a combination thereof.

14. The plane semiconductor inverter of claim 12, wherein said gate conductor comprises doped poly-Si, a metal material, a midgate material and the combination thereof.

15. The plane semiconductor inverter of claim 11, further comprising a shallow trench isolation on said insulator layer to render said first source, said first drain, said second source and said second drain mutually electrically insulated.

16. A method for forming a plane MOS, comprising:
providing a substrate having an insulator layer thereon, an active area directly on the surface of said insulator layer and a shallow trench isolation surrounding said active area, wherein the surface of said insulator layer is substantially parallel with the surface of said substrate;
adjusting the threshold voltage of said active area;
forming a first hard mask covering said active area and said shallow trench isolation and a second patterned hard mask covering said first hard mask, said second patterned hard mask exposing a gate region, a source region and a drain region of said first hard mask;
etching said source region and said drain region of said first hard mask to expose said active area of said source region and said active area of said drain region;
respectively forming a source and a drain in said exposed active area of said source region and said exposed active area of said drain region;
forming a passivation layer to cover partially exposed said first hard mask, said patterned second hard mask, said source and said drain;
etching said gate region to expose said insulator layer and forming a gate trench;
forming a gate insulator layer on the sidewall of said gate trench;
substantially filling said gate trench with a conductive material to form a gate;
etching said conductive material back;
removing said passivation layer; and
forming a gate contact plug, a source contact plug and a drain contact plug respectively on said gate, said source and said drain to form said plane MOS.

17. The method of claim 16, wherein said gate comprises said conductive material and said gate insulator layer.

18. The method of claim 17, wherein said conductive material comprises a composite material.

19. The method of claim 17, wherein said conductive material comprises doped poly-Si, a metal material, a midgate material and the combination thereof.

20. The method of claim 17, wherein said gate insulator layer comprises silicon dioxide, high-k dielectric material, or a combination thereof.

21. The method of claim 16, wherein said first hard mask and said second hard mask respectively have high etching selectivity.

22. The method of claim 16, wherein said shallow trench isolation contacts said gate, said source and said drain.

23. A method for forming a plane dual-channel structure, said plane dual-channel structure comprising a PMOS and an NMOS sharing a common gate, said method comprising:
providing a substrate having an insulator layer thereon, a PMOS active area directly on the surface of said insulator layer, an NMOS active area directly on the surface of said insulator layer directly on the surface of said insulator layer, a gate active area directly on the surface of said insulator layer and a shallow trench isolation surrounding said PMOS active area and said NMOS active area, wherein the surface of said insulator layer is substantially parallel with the surface of said substrate;
adjusting the threshold voltage of said PMOS active area;
adjusting the threshold voltage of said NMOS active area;
forming a first hard mask covering said PMOS active area, said NMOS active area, said gate active area and said shallow trench isolation and a patterned second hard mask covering said first hard mask, said patterned second hard mask defining a PMOS source region, a PMOS drain region, an NMOS source region, an NMOS drain region and said gate region;
etching said first hard mask back to expose said PMOS active area of said PMOS source region, said PMOS active area of said PMOS drain region, said NMOS active area of said NMOS source region and said NMOS active area of said NMOS drain region through said PMOS source region, said PMOS drain region, said NMOS source region and said NMOS drain region;
forming a PMOS source and a PMOS drain in said exposed PMOS active area of said PMOS source region and said exposed PMOS active area of said PMOS drain region;
forming an NMOS source and an NMOS drain in said exposed NMOS active area of said NMOS source region and said exposed NMOS active area of said NMOS drain region;
forming a passivation layer to cover partially exposed said first hard mask, said second hard mask, said PMOS source, said PMOS drain, said NMOS source and said NMOS drain;
etching said gate region to expose the corresponding insulator layer and forming a gate trench;
forming a gate insulator layer on the sidewall of said gate trench;
filling said gate trench with a conductive material to form a gate;
etching said conductive material back;
removing said passivation layer; and
forming a gate contact plug, a PMOS source contact plug, a PMOS drain contact plug, an NMOS source contact plug and an NMOS drain contact plug respectively on said gate, said PMOS source, said PMOS drain, said NMOS source and said NMOS drain to form said plane dual-channel structure.

24. The method of claim 23, wherein said gate comprises said conductive material and said gate insulator layer.

25. The method of claim 24, wherein said conductive material comprises a composite material.

26. The method of claim 23, wherein said conductive material comprises a P-type gate material for said PMOS and an N-type gate material for said NMOS.

27. The method of claim 23, wherein the work function of said conductive material is between the conduction band and the valence band of said conductive material.

28. The method of claim 23, wherein said conductive material is selected from a group consisting of MoN and TaSIN.

29. The method of claim 23, wherein said gate insulator layer comprises silicon dioxide, high-k dielectric material, or a combination thereof.

30. The method of claim 23, wherein the first hard mask and the second hard mask respectively have high etching selectivity.

31. The method of claim 23, wherein forming said PMOS source and said PMOS drain comprises an implantation and an annealing step.

32. The method of claim 23, wherein forming said NMOS source and said NMOS drain comprises an implantation and an annealing step.
